(19) United States
(12) Patent Application Publication
(10) Pub. No.: US 2007/0172591 A1
(43) Pub. Date: Jul. 26, 2007

(54) METHOD OF FABRICATING ZnO FILM AND THIN FILM TRANSISTOR ADOPTING THE ZnO FILM

(75) Inventors: O-gweon SEO, Yongin-si (KR); Jungyol JO, Suwon-si (KR)

Correspondence Address: CANTOR COLBURN, LLP, 55 GRIFFIN ROAD SOUTH, BLOOMFIELD, CT, 06002, US

(73) Assignees: SAMSUNG ELECTRONICS CO., LTD., Suwon-si (KR); AJOU UNIVERSITY INDUSTRY COOPERATION FOUNDATION, Suwon-si (KR)

(21) Appl. No.: 11/625,016

(22) Filed: Jan. 19, 2007

(30) Foreign Application Priority Data
Jan. 21, 2006 (KR) 10-2006-0006569
Dec. 11, 2006 (KR) 10-2006-0125694

(51) Int. Cl. C23C 16/00; B05D 7/00

(52) U.S. Cl. 427/248.1; 427/402

(57) ABSTRACT

Provided is a method of fabricating a low temperature ZnO polycrystalline film and a thin film transistor (TFT) adopting the low temperature ZnO polycrystalline film. The method includes growing ZnO on a substrate at a first temperature for a first time using Metal Organic Chemical Vapor Deposition (MOCVD) to form a ZnO buffer layer, and heating the substrate at a temperature lower than the first temperature to grow ZnO on the ZnO buffer layer for a second time longer than the first time so as to form a ZnO film.

### CROSS-REFERENCE TO RELATED APPLICATION

This application claims priority to Korean Patent Application No. 10-2006-0006569, filed on Jan. 21, 2006, and Korean Patent Application No. 10-2006-0125694, filed on Dec. 11, 2006, and all the benefits accruing therefrom under 35 U.S.C. § 119, the contents of which in their entirety are herein incorporated by reference.

### BACKGROUND OF THE INVENTION

1. Field of the Invention

The present invention relates to a method of fabricating a ZnO film, and more particularly, to a method of fabricating a ZnO film and a thin film transistor (“TFT”) adopting the ZnO film using low temperature Metal Organic Chemical Vapor Deposition (“MOCVD”).

2. Description of the Related Art

TFT-liquid crystal displays (“LCDs”) using silicon use glass substrates and thus are heavy and inflexible. Thus, the TFT-LCDs may not be fabricated as flexible displays. Organic semiconductor and metal oxide semiconductor materials have been recently studied to solve this problem. ZnO as a metal oxide semiconductor is applied to TFTs, sensors, optical wave devices, piezoelectric elements, and the like. ZnO films grown at a high temperature of greater than or equal to about 400° C. generally have superior characteristics. However, such high temperature film growth is used in limited substrate materials and thus cannot be used for plastic substrates or the like, which have a low heat resistance.

It has been found that a substrate can be heated at a temperature of 350° C. to 450° C. to grow ZnO (refer to U.S. Pat. No. 6,808,743), and that a ZnO crystal is generally grown at a temperature of 600° C. to 900° C. (refer to U.S. Pat. No. 6,664,565). The Hosono Group at the University of Tokyo in Japan has found that an oxide including an appropriate mixture of In, Ga, and Zn can be grown at room temperature using a laser ablation method (refer to PCT Appl. No. PCT/JP05/03273). However, it is difficult to adjust component ratios of In, Ga, and Zn, and the oxide cannot be grown using a MOCVD method. As a result, it is difficult to mass-produce ZnO films.

### SUMMARY OF THE INVENTION

The present invention provides a method of fabricating a ZnO film of which ZnO can be grown at a low temperature and a thin film transistor (TFT) adopting the ZnO film.

The present invention also provides a method of growing ZnO on a substrate such as plastic which has a low heat resistance.

According to an aspect of the present invention, there is provided a method of fabricating a ZnO film, including: growing ZnO on a substrate at a first temperature and for a first time using MOCVD (Metal Organic Chemical Vapor Deposition) to form a ZnO buffer layer; and heating the substrate at a temperature lower than the first temperature to grow ZnO on the ZnO buffer layer for a second time longer than the first time so as to form a ZnO film.

The first temperature may be greater than or equal to 300° C., and the second temperature may be less than or equal to 300° C. The substrate is plastic or silicon.

According to another aspect of the present invention, there is provided a method of fabricating a ZnO TFT having a substrate, a ZnO semiconductor layer formed on a surface of the substrate, a source and a drain contacting the ZnO semiconductor layer, and a gate forming an electric field around the ZnO semiconductor layer, the method including: forming the ZnO semiconductor layer; growing ZnO on the substrate at a first temperature and for a first time using MOCVD to form a ZnO buffer layer; and heating the substrate at a temperature lower than the first temperature to grow ZnO on the ZnO buffer layer for a second time longer than the first time so as to form a ZnO film.

### BRIEF DESCRIPTION OF THE DRAWINGS

The above and other features and advantages of the present invention will become more apparent by describing in detail exemplary embodiments thereof with reference to the attached drawings in which:

FIGS. 1 through 3 are cross-sectional views illustrating a method of fabricating a low temperature ZnO film;

FIGS. 4 and 5 are cross-sectional views of ZnO thin film transistors (TFTs);

FIGS. 6 through 8 are graphs illustrating the results of quantitative analyses of elements of a ZnO film by an X-ray photoelectron spectroscopy (“XPS”); and

FIGS. 9 and 10 are graphs illustrating variations in drain current characteristics of TFT samples.

### DETAILED DESCRIPTION OF THE INVENTION

Hereinafter, a method of fabricating a ZnO semiconductor film and a ZnO thin film transistor (TFT) will be described.

It will be understood that when an element is referred to as being “on” another element, it can be directly on the other element or intervening elements may be present therebetween. In contrast, when an element is referred to as being “disposed on” another element, the elements are understood to be in at least partial contact with each other, unless otherwise specified.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

A ZnO crystal film having a high quality semiconductor characteristic such as a metal oxide may be formed on a plastic substrate which has low heat resistance, and a ZnO TFT is subsequently fabricated using the ZnO crystal film. ZnO is typically grown at a temperature of greater than or equal to about 400° C. to obtain high quality ZnO. However, a ZnO film cannot be formed on a plastic film needed for a flexible display using such methods, without also deforming or damaging the plastic substrate.

As disclosed herein, a ZnO buffer layer is formed at a first temperature useful for obtaining a high quality ZnO film, i.e., at a temperature of greater than or equal to about 400° C., for a first time during which a substrate is not thermally deformed, for example, within about 1 minute. Here, the ZnO buffer layer may have a thickness of 1 nm to 1,000 nm.

After the ZnO buffer layer is obtained, the temperature of the substrate is reduced to a second temperature at which thermal deformation does not occur, for example, to a temperature of 200° C. to 250° C., and then a ZnO film is grown on the ZnO buffer layer for a second time longer than the first time, i.e., for enough time to grow the ZnO film. In other words, ZnO having a high quality crystal structure is grown on the ZnO buffer layer at the lower second temperature, and thus a high quality ZnO film can be grown at a low temperature.

ZnO is formed as a ZnO film by using two processes. In the first process, a metal atom Zn and an organic material are separated from diethylzinc (“DEZ”) as a precursor, and in the second process, the metal atom Zn is combined with oxygen. However, the DEZ precursor is not readily decomposed into an organic metal and an organic material at a low temperature of 300° C. or less, and this is a first reason for the difficulty in growing a ZnO film. Further, initiating growth of ZnO on a surface of an insulator is difficult due to a lack of nucleation sites, which is a second reason for the difficulty in growing the ZnO film. Overcoming these obstacles can be accomplished by forming minute nuclei to assist in growing a ZnO layer. To overcome the first problem, the amount of oxygen in the atmosphere is increased considerably, instead of reducing the temperature of the substrate, so as to promote the decomposition of the organic material and the metal atom. A thin buffer layer (of minute nuclei) is grown at a temperature of 400° C. to solve the second problem. The flow ratio of oxygen to DEZ used is increased to about 1,000 times greater than that used in the conventional growing conditions, i.e., about 1,000:1, and ZnO is grown at a temperature of greater than or equal to about 400° C. for about 1 minute.

For initial growth of a high quality ZnO buffer layer that starts on a substrate, a ZnO nano-crystal of the ZnO buffer layer operates as a starting substrate (i.e., nucleation site) for growing the ZnO film that is to be formed after the ZnO buffer layer. In this way, a high quality ZnO film is obtained on the substrate even at a low temperature. A TFT fabricated using the ZnO film using such a fabrication method has a mobility measured at 1 cm²/Vs to 10 cm²/Vs.

An exemplary embodiment of a method of fabricating a ZnO film will now be described.

1) Atmospheric Pressure Metal Organic Chemical Vapor Deposition (MOCVD), Horizontal Reactor

2) Nitrogen Flow Rate: 2,000 sccm

3) Oxygen Flow Rate: 180 sccm

4) Temperature of DEZ: 0° C., Bubbler Flow Rate: 15 sccm

5) Substantial Flow Rate of DEZ: (0° C. Vapor Pressure 5 torr) 0.098 sccm

6) Oxygen/DEZ Flow Ratio 1,800:1

7) Growing Time of ZnO Film: 4 Minutes-10 Minutes

8) Total Thickness of ZnO Film: 20-70 nm

A process for growing a ZnO film will now be described.

As shown in FIG. 1, a ZnO buffer layer 11 is formed on a substrate 10 using MOCVD under the above-mentioned conditions. The ZnO buffer layer 11 is grown at a temperature of greater than or equal to about 300° C., specifically about 400° C., for about 1 minute.

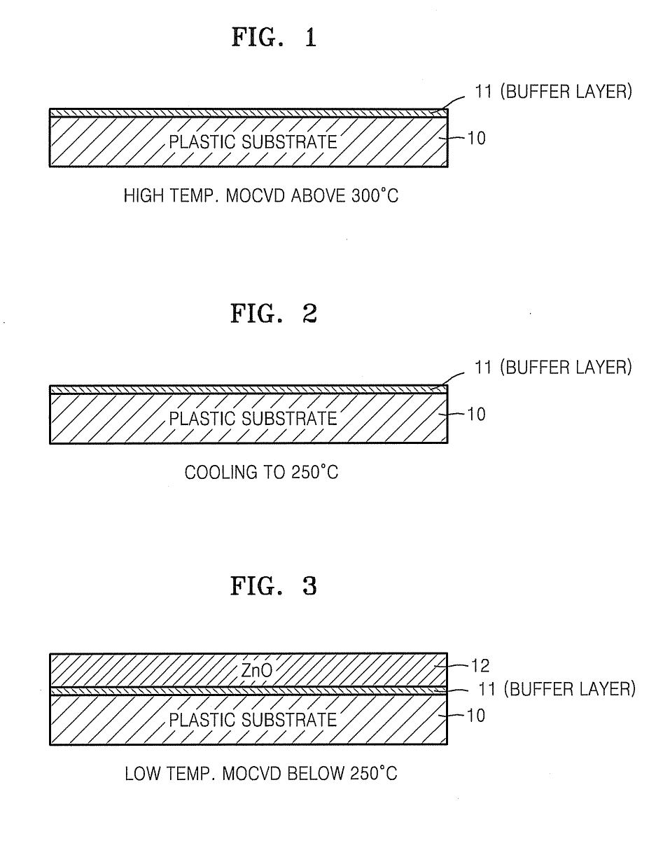

As shown in FIG. 2, after the buffer layer 11 is formed, the substrate 10 which is at a high temperature is cooled for about 3 minutes in a reactor so as to reduce the temperature of the substrate 10 to less than or equal to 300° C., specifically to about 250° C.

As shown in FIG. 3, a ZnO film is grown for 3 minutes to 10 minutes using MOCVD under the above-mentioned conditions with a thickness of the ZnO film being adjusted to 20 nm to 70 nm so as to obtain a target high quality ZnO film. Here, the flow ratio of oxygen to DEZ precursor is adjusted to greater than or equal to about 1,000:1, specifically to about 1,800:1.

In general, a flow ratio of oxygen to DEZ used at a temperature of greater than or equal to about 400° C. is 5:1 to 10:1. In the present experiment, the substrate 10 has a low temperature, and thus a reaction between the precursor and oxygen is promoted with a flow ratio of about 1,800:1. The flow_ratio of oxygen to the precursor is very high, but a flow ratio of oxygen to Zn is about 0.8:1 according to the results of a component analysis performed through an X-ray photoelectron spectroscopy (“XPS”).

A ZnO film grown using the above-described method of the present embodiment is used to prepare a TFT which includes a substrate, a ZnO semiconductor layer formed on a surface of the substrate, a source and a drain disposed on and contacting a surface of the ZnO semiconductor layer, and a gate forming an electric field around the ZnO semiconductor layer. The source and drain are typically provided on the same surface of the ZnO semiconductor layer, and the gate can be on a surface of the ZnO semiconductor layer opposite the source and drain. In an embodiment, a top contact TFT includes a source and a drain disposed on and contacting the top of a ZnO semiconductor layer. In another embodiment, a bottom contact TFT includes a source and a drain disposed on and contacting the bottom of a ZnO semiconductor layer.

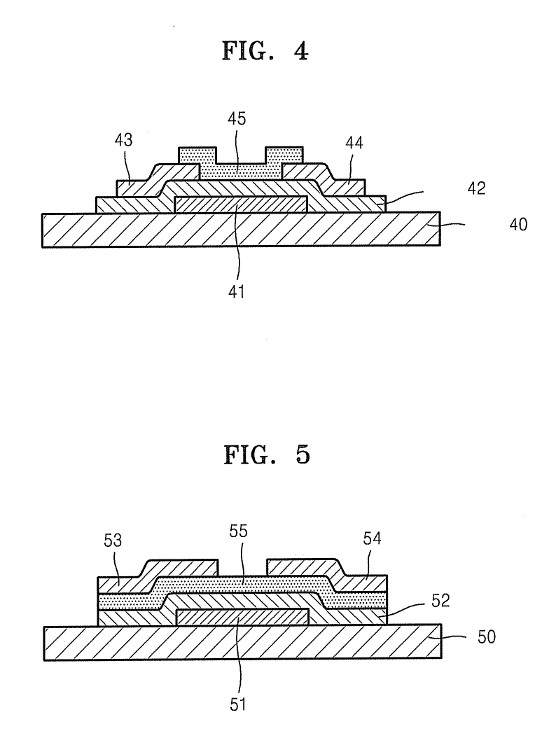

FIG. 4 is a cross-sectional view of a TFT using a general top contact method. A gate 41 is formed on a surface of a substrate 40, and an insulator 42 is positioned on a surface of the gate 41 opposite the substrate 40. A source 43 and a drain 44 spaced apart from each other and based on (i.e., overlapping with, as seen in the cross-sectional view) the gate 41, are positioned on a surface of the insulator 42 opposite the gate 41 or substrate 40. A ZnO semiconductor layer 45 is disposed between the source 43 and the drain 44 on the insulator 42, and a portion of both sides of the ZnO semiconductor layer 45 overlap with a surface of the source 43 and a surface of the drain 44 opposite the insulator 42.

In order to obtain the TFT shown in FIG. 4, the gate 41, the insulator 42, the source 43, and the drain 44 must be formed on the substrate 40 before the ZnO semiconductor layer 45 (also referred to as a “ZnO film”) is grown. Forming of a ZnO buffer layer (not shown) at a high temperature and depositing of a thick ZnO at a low temperature are performed on a substrate 40 on which such elements are formed. The ZnO film obtained is patterned to have an island shape, a portion of both sides of which are placed on the source 43 and the drain 44.

FIG. 5 is a cross-sectional view of a TFT using a general bottom contact method. A gate 51 is formed on a surface of the substrate 50, and an insulator is positioned on a surface of the gate 51 opposite the substrate 50. A ZnO semiconductor layer 55 is formed on a surface of the insulator 52 opposite the gate 51 or substrate 50, and a source 53 and a drain 54 spaced apart from each other based on the gate 53 are positioned on a surface of the ZnO semiconductor layer 55 opposite the insulator 52. The ZnO semiconductor layer 55 extends across the gate 51 toward the outside of both ends of the gate 51, and the source 53 and the drain 54 are formed on the extending parts of the ZnO semiconductor layer 55.

In order to fabricate the TFT shown in FIG. 5, the gate 51 and the insulator 52 must be formed on the substrate 50 before a ZnO film is grown. Forming of a ZnO butter layer at a high temperature and depositing of thick ZnO at a low temperature are performed on the insulator 52. The source 53 and the drain 54 are obtained from an aluminum layer formed on a finally obtained ZnO film (from which the ZnO semiconductor layer 55 is patterned), and the source 53, the drain 54, and the ZnO semiconductor layer are patterned using a conventional method.

In the TFTs shown in FIGS. 4 and 5, the sources 43, 53 and the drains 44, 54 are formed of a typical metal such as aluminum, or the like, and the insulators are formed of an insulating material such as SiO₂, Si₃N₄, or the like generally used in a TFT. Mobility has a value between 1 cm²/Vs and 10 cm²/Vs according to a voltage current characteristic measured from a TFT fabricated with such a structure. Here, the insulators are formed of SiO₂ to a thickness of about 110 nm. The length (i.e., the dimension at right angles to the views of FIGS. 4 and 5) and width (i.e., the distance between source and drain) of the channel between the source 43, 53 and drain 44, 54 in ZnO semiconductor layer 45, 55 are about 15 microns and about 500 microns, respectively.

The TFTs shown in FIGS. 4 and 5 are TFTs fabricated using a bottom gate method by which a gate is disposed under a semiconductor layer. According to another aspect of the present invention, a TFT may be obtained using a top gate method by which a gate is positioned above a semiconductor layer.

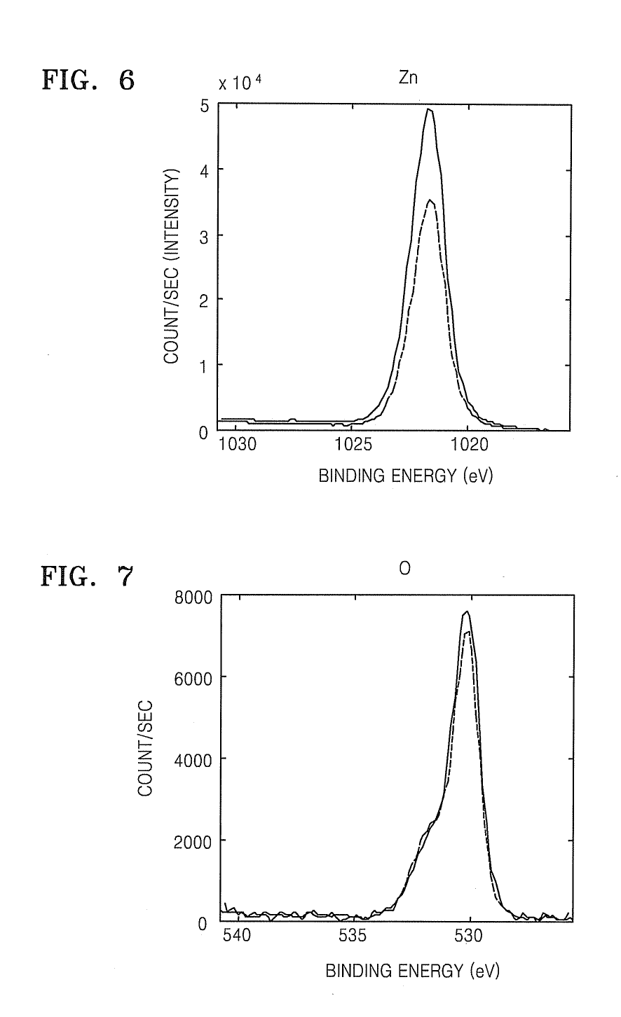

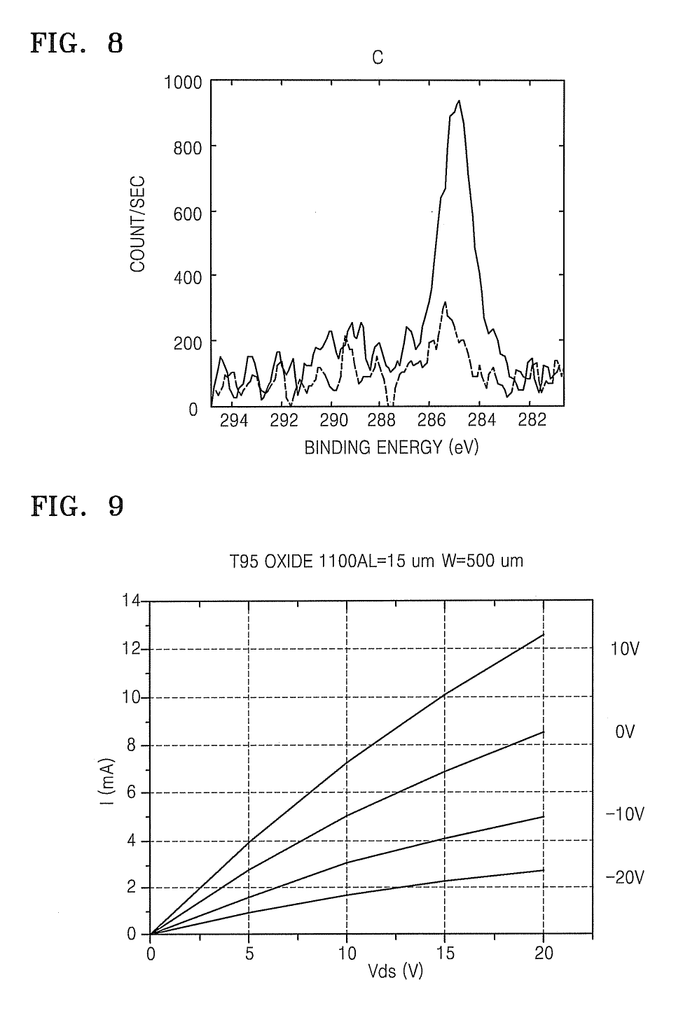

Tables 1 below and FIGS. 6 through 8 show the results of a quantitative analysis of elements of a ZnO film performed using an XPS. An increase in the amount of oxygen activates the decomposition of the metal-carbon bond of DEZ. Carbon-based impurities C are also desirably reduced as these impurities can, when present in an active semiconductor layer, act as electron or hole traps that can interrupt current flow and inhibit operation of the semiconductor device.

TABLE 1

| | O₂ flow rate | | | | |
|---|---|---|---|---|---|
| | during deposition | | | | O/Zn |
| Analyzed region | the ZnO film | C | O | Zn | ratio |
| Surface of a ZnO film | O₂: 50 sccm | 13.74 | 44.93 | 41.33 | 1.09 |
| (As-Received) | O₂: 100 sccm | 10.85 | 40.55 | 48.6 | 0.83 |
| Undersurface of a | O₂: 50 sccm | 13.62 | 42.9 | 42.48 | 0.99 |
| ZnO film | O₂: 100 sccm | 2.28 | 42.16 | 55.55 | 0.76 |
| (After etch by sputter) | | | | | |

FIGS. 6 through 8 show the results (marked with dotted lines) of a quantitative analysis of a ZnO film when oxygen of 50 sccm is injected during deposition of the ZnO and the results (marked with solid lines) of a quantitative analysis of the ZnO film when oxygen of 100 sccm is injected during deposition of the ZnO. The amount of carbon remaining as a trap in a ZnO semiconductor layer is decreased from 10.85 to 2.39 corresponding to the increase in the amount of oxygen injected. In other words, a decomposition of a metal atom and an organic material of a precursor is promoted with the additional oxygen. Also, the amount of oxygen is doubled, but the flow ratio of oxygen to Zn decreased from 0.93 to 0.76. This means that the majority amount of added oxygen is used for decomposing the organic portion of the DEZ precursor and thus there is a lack of oxygen to be combined with Zn. Thus, a still greater amount of oxygen is should be injected to provide complete oxidation of the zinc. It has been observed that injection of oxygen at 180 sccm provides optimal decomposition and oxidation conditions.

TABLE 2

| | Supply Amount | Growing | | Drain | |
|---|---|---|---|---|---|
| Sample | of DEZn/O₂ | Temperature | Buffer | Current | Mobility |
| No. | (sccm) | (° C.) | Layer | (I) | (cm²/Vs) |
| 1 | 0.0986/120 | 250 | Yes | 0.5 | 2.1 |
| 2 | 0.0986/120 | 200 | No | 0.15 | 0.6 |
| 3 | 0.0986/120 | 200 | No | 0.001 | 0.004 |
| 4 | 0.0986/180 | 250 | Yes | 1.18 | 5 |
| 5 | 0.0986/180 | 200 | No | 0.24 | 1.0 |
| 6 | 0.0986/180 | 200 | Yes | 0.4 | 1.7 |
| 7 | 0.0986/120 | 200 | Yes | 0.35 | 1.5 |
| 8 | 0.0986/180 | 200 | No | 0.0016 | 0.007 |

Referring to Table 2, in the case of a TFT including a buffer layer, mobility is about 1.5 cm²/Vs at a low growing temperature of 200° C. A 40-inch organic light-emitting diode (“OLED”) display has a useful minimum mobility of about 1.3 cm²/Vs, and thus samples 1, 4, 6, and 7 in Table 2 denote TFTs grown at a low temperature are practicable. However, TFTs corresponding to samples 2, 3, 5, and 8 which do not include buffer layers show poor mobility. In particular, if the samples 2, 3, 5, and 8 are grown at a temperature of 250° C., the samples 2, 3, 5, and 8 show a poor mobility of about 1.0 cm²/Vs. As shown in Table 2, buffer layers grown at a high temperature using a fabrication method of an embodiment are adopted so as to fabricate TFTs having high mobility even at a temperature of 200° C. Sample 7 obtains a mobility of about 1.5 cm²/Vs. Thus, it can be expected that mobility of about 1.3 cm²/Vs can be realized even at a temperature slightly lower than 200° C.

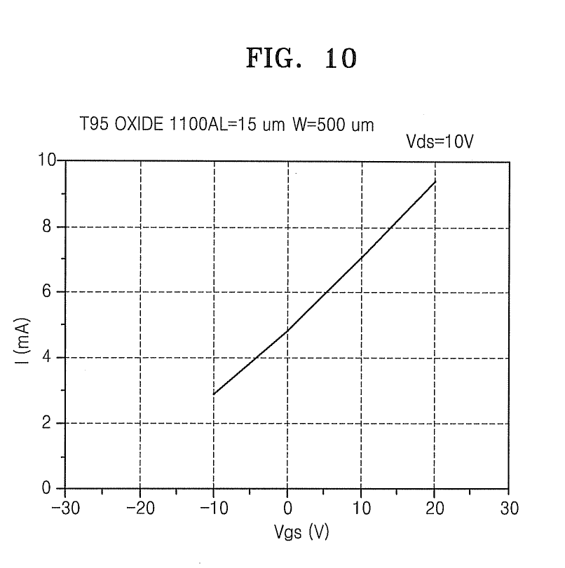

FIGS. 9 and 10 are graphs illustrating variations in drain current characteristics of TFT samples fabricated under the same conditions as those of sample 4 shown in Table 2. Mobility can be calculated as in Equation 1:

$$I = \frac{W \cdot μ \cdot C}{L} ( {V}_{GS} - {V}_{th} ) {V}_{DS} \\ where \\ C = 327 μ F \text{/} {m}^{2} \qquad ( 1 )$$

where L is a length of the channel, W is a width of the channel, μ is a electron mobility and C is a constant as described above. The characteristics of a TFT fabricated under the above-mentioned conditions are measured to calculate mobility. Here, a drain current of a ZnO semiconductor layer having a dielectric constant of 4 and a thickness d of 110 nm is measured as 2.75 mA under the conditions that a threshold voltage Vₜₕ=−30 V, a source-drain voltage V_{DS}=5 V, and a gate-source voltage V_{GS}=0. Mobility is calculated as 16.8 cm²/Vs.

Table 3 below shows the results of mobility (unit: cm²/Vs) measured with respect to 10 TFTs obtained under conditions in which Zn/O₂ is supplied and grown on a buffer layer at a temperature of 250° C. in a flow ratio of DEZ to O₂ of 0.986/180 sccm.

TABLE 3

| | Sample | | | | | | | | | |
|---|---|---|---|---|---|---|---|---|---|---|
| | 1 | 2 | 3 | 4 | 5 | 6 | 7 | 8 | 9 | 10 |
| Mobility | 17.6 | 18.3 | 17.2 | 13.3 | 14.6 | 15.5 | 17.3 | 15.7 | 16.1 | 14.8 |

According to the present invention, a ZnO polycrystalline film having high mobility and a TFT adopting the ZnO polycrystalline film can be obtained even at a low temperature of about 200° C. Also, using this method, a ZnO film can be formed on a substrate such as plastic which has low heat resistance, and thus a ZnO TFT can be formed on a plastic substrate.

The present invention can be applied to all types of articles using ZnO films, particularly, to flexible displays in which TFTs are to be formed on flexible substrates such as plastic.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a ZnO film, comprising:
growing ZnO on a substrate at a first temperature for a first time using MOCVD (Metal Organic Chemical Vapor Deposition) to form a ZnO buffer layer; and
heating the substrate at a temperature lower than the first temperature to grow ZnO on the ZnO buffer layer for a second time longer than the first time so as to form a ZnO film.

2. The method of claim 1, wherein the first temperature is greater than or equal to 300° C., and the second temperature is less than or equal to 300° C.

3. The method of claim 1, wherein the substrate is plastic or silicon.

4. The method of claim 1, wherein the second temperature is about 250° C.

5. The method of claim 1, wherein a thickness of the ZnO buffer layer is within a range between 1 nm and 1,000 nm.

6. The method of claim 1, wherein DEZ (diethylzinc) is used as a precursor for growing the ZnO.

7. The method of claim 6, wherein when the ZnO buffer layer is grown, O₂:DEZ are supplied in a flow ratio of greater than or equal to about 1,000:1.

8. The method of claim 7, wherein when the ZnO film is grown, O₂:DEZ are supplied in a flow ratio of greater than or equal to about 1800:1.

9. The method of claim 4, wherein when the ZnO film is grown, O₂:DEZ are supplied in a flow ratio of greater than or equal to 1,000:1.

10. The method of claim 9, wherein when the ZnO film is grown, O₂:DEZ are supplied in a flow ratio of greater than or equal to about 1,800:1.

11. A method of fabricating a ZnO TFT (thin film transistor) comprising a substrate, a ZnO semiconductor layer formed on a surface of the substrate, a source and a drain disposed on and contacting a surface of the ZnO semiconductor layer opposite the substrate, and a gate forming an electric field around the ZnO semiconductor layer, comprising:
forming the ZnO semiconductor layer by;
growing ZnO on the substrate at a first temperature for a first time using MOCVD to form a ZnO buffer layer; and
heating the substrate at a temperature lower than the first temperature to grow ZnO on the ZnO buffer layer for a second time longer than the first time so as to form a ZnO film.

12. The method of claim 11, wherein the first temperature is greater than or equal to 300° C., and the second temperature is greater than or equal to 300° C.

13. The method of claim 11, wherein the substrate is silicon or plastic.

14. The method of claim 11, wherein the second temperature is about 250° C.

15. The method of claim 11, wherein DEZ is used as a precursor for growing the ZnO.

16. The method of claim 15, wherein when the ZnO film is grown, O₂:DEZ are supplied in a flow ratio of greater than or equal to about 1,000:1.

17. The method of claim 16, wherein O₂:DEZ is supplied in a flow ratio of about 1,800:1.
